(19) United States
(12) Patent Application Publication
(10) Pub. No.: US 2005/0285160 A1
(43) Pub. Date: Dec. 29, 2005

(54) Methods for forming semiconductor wires and resulting devices

(76) Inventor: Peter L.D. Chang, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/879,765

(22) Filed: Jun. 28, 2004

(51) Int. Cl. H01L 29/78; H01L 21/8234

(52) U.S. Cl. 257/288; 257/618; 438/197; 438/618

(57) ABSTRACT

Methods for forming a wire from silicon or other semiconductor material are disclosed. Also disclosed are various wire structures and devices including these wire structures (e.g., transistors). A wire structure may comprise a wire that extends between two spaced-apart anchors, with each anchor affixed to an underlying substrate and the wire spaced apart from the substrate. Other embodiments are described and claimed.

### RELATED APPLICATION

This application is related to U.S. patent application Ser. No. ______ [docket no. P19533], entitled “Methods for Forming Semiconductor Wires and Resulting Devices,” filed on even date herewith.

### FIELD OF THE INVENTION

The invention relates generally to the manufacture of integrated circuit devices and, more particularly, to the formation of wires in silicon or other semiconductor materials.

### BACKGROUND OF THE INVENTION

A modern microprocessor may include several million transistors and other circuit elements (e.g., resistors, capacitors, diodes, etc.) formed on a semiconductor die. Transistors may be used to form both logic circuitry and memory circuitry (e.g., SRAM or DRAM) on a processing device. In future generations of processors, as well as other integrated circuit devices, it is expected that the number of transistors will continue to increase. At the same time, however, it may be desirable to decrease die size. Thus, semiconductor manufacturers may be faced with the problem of fabricating increasing numbers of transistors on a smaller semiconductor “footprint.” One way to increase the number of transistors while decreasing die size is to shrink the size of the transistors themselves. However, as manufacturers reduce the feature sizes of transistors, the capabilities of conventional lithography may eventually be exceeded.

### BRIEF DESCRIPTION OF THE DRAWINGS

FIG. 1 is a block diagram illustrating an embodiment of a method for forming a wire from silicon or other semiconductor material.

FIGS. 2A-2R are schematic diagrams illustrating embodiments of the method shown in FIG. 1.

FIG. 3A is a schematic diagram illustrating a perspective view of an embodiment of a wire, as may be fabricated according to the method of FIG. 1.

FIG. 3B is a schematic diagram illustrating an embodiment of a transistor device including the wire of FIG. 3A.

FIG. 4 is a block diagram illustrating another embodiment of a method for forming a wire from silicon or other semiconductor material.

FIGS. 5A-5k are schematic diagrams illustrating embodiments of the method shown in FIG. 4.

FIG. 6A is a schematic diagram illustrating a perspective view of an embodiment of a wire, as may be fabricated according to the method of FIG. 4.

FIG. 6B is a schematic diagram illustrating an embodiment of a transistor device including the wire of FIG. 6A.

FIG. 7 is a schematic diagram illustrating an embodiment of a semiconductor wafer upon which any of the disclosed embodiments of a wire may be formed.

FIG. 8 is a schematic diagram illustrating an embodiment of a computer system, which may include a component having a circuit element formed according to one or more of the disclosed embodiments.

### DETAILED DESCRIPTION OF THE INVENTION

Disclosed herein are various embodiments of a method for forming a wire in silicon, as well as transistor devices including such a silicon wire. In one embodiment, a wire formed according to one or more of the disclosed embodiments has a diameter (or other minimum width dimension) of approximately 50 nm or less (e.g., a “nanowire”). However, it should be understood that the disclosed methods are not limited to the formation of silicon wires and that the disclosed methods may be used to fabricate wires in other semiconductor materials. It should be further understood that the disclosed embodiments are not limited to the formation of “nanowire” devices and that wires of any scale (e.g., greater than 50 nm in diameter) may be formed according to the disclosed embodiments. In addition, it should be understood that the disclosed wires are not limited in application to the formation of transistors, and in other embodiments the disclosed wires may find application in other circuit elements or devices.

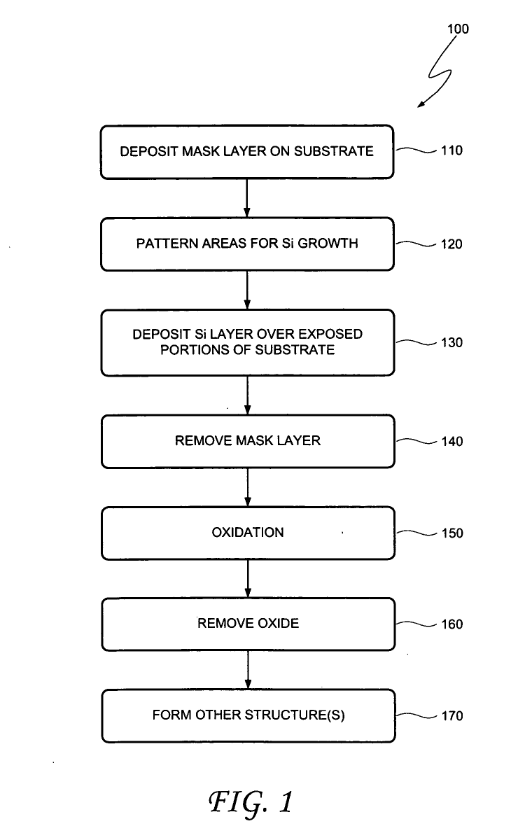

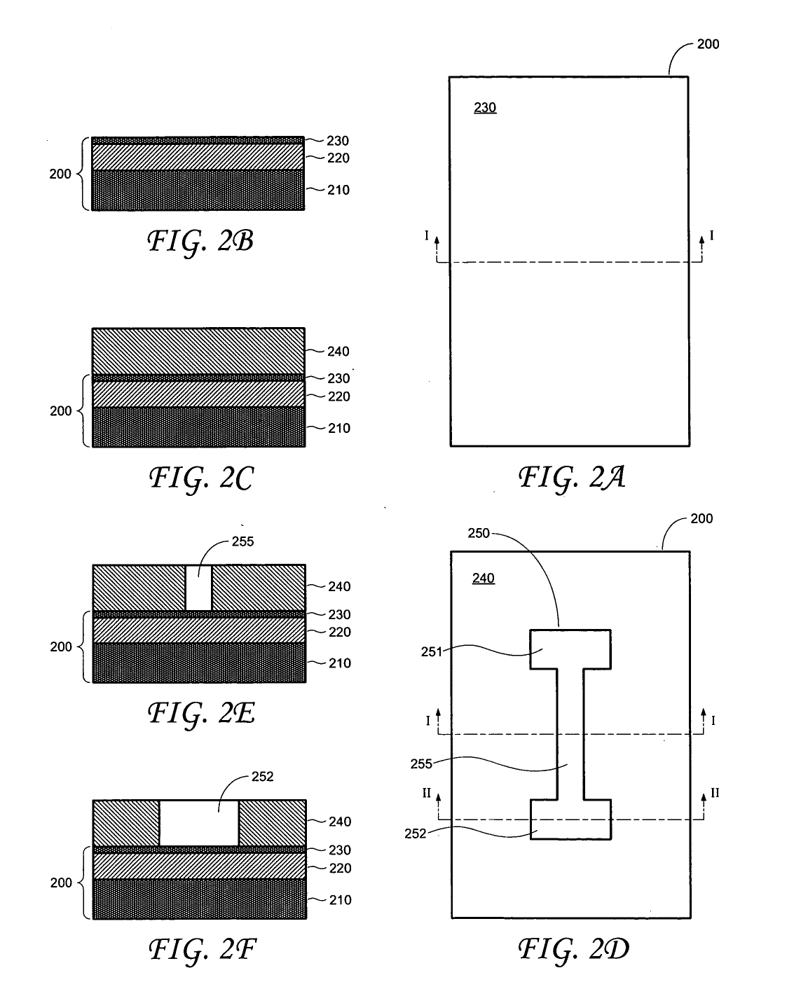

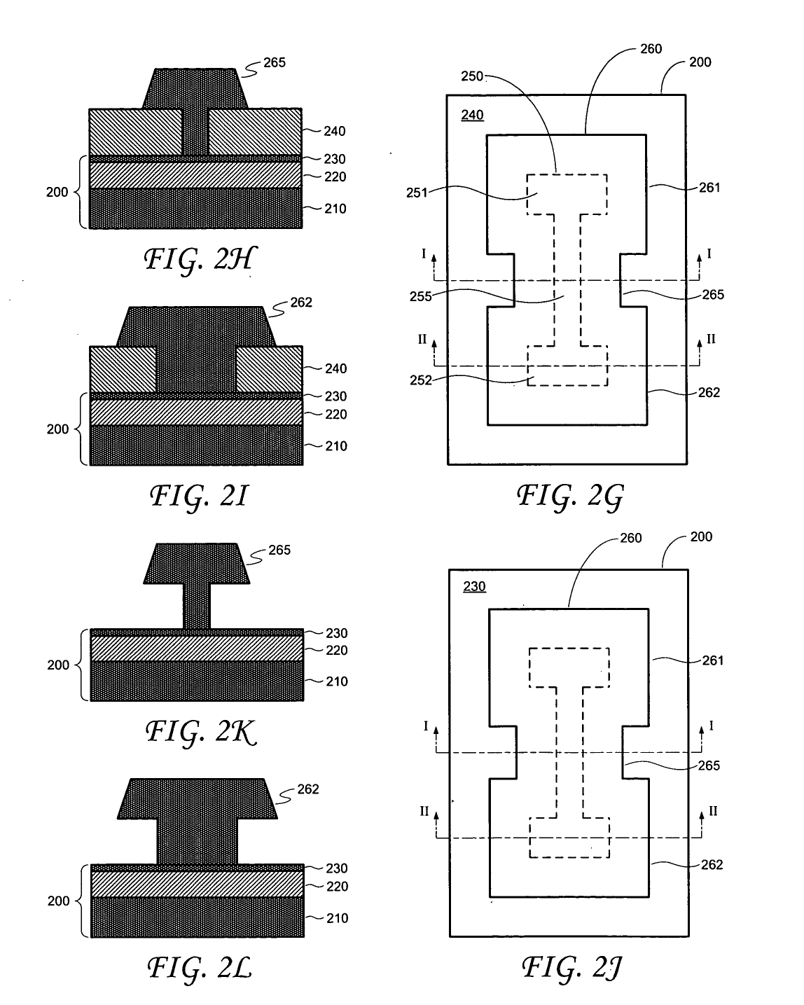

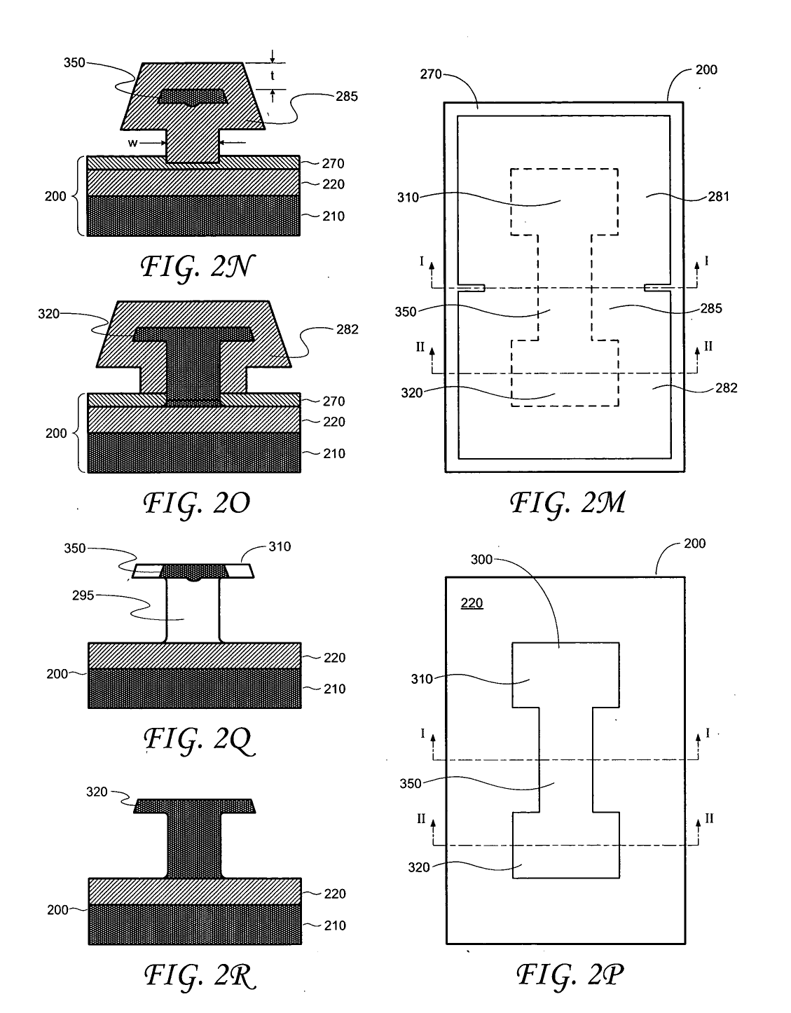

Illustrated in FIG. 1 is an embodiment of a method for forming a wire from silicon or other semiconductor material. The method of FIG. 1 is further illustrated, by way of example, in the schematic diagrams of FIGS. 2A through 2R. Reference should be made to each of FIGS. 2A through 2R, as called out in the text below.

Referring first to FIGS. 2A and 2B, a substrate 200 is shown. A plan view of the substrate is shown in FIG. 2A, and a cross-sectional view of the substrate, as taken along line I-I in FIG. 2A, is shown in FIG. 2B (and FIG. 2C). In one embodiment, the substrate 200 comprises a base layer of a semiconductor material 210, a layer of an insulating material 220 overlying the base layer 210, and a layer of a semiconductor material 230 overlying the insulating layer 220. Substrate 200 may, in one embodiment, comprise a wafer upon which a number of integrated circuit (IC) devices are to be formed. In one embodiment, the semiconductor layer 230 comprises silicon, and the insulating layer 220 comprises silicon dioxide (SiO₂). In another embodiment, the base layer 210 also comprises silicon. In one embodiment, the substrate 200 comprises a silicon-on-insulator (SOI) wafer. For ease of explanation, in the following description, it is assumed that the semiconductor layer 230 comprises silicon and, further, that the wire will be formed from silicon. However, it should be understood that the disclosed embodiments are not limited to the use of silicon and, further, that the substrate 200 and disclosed wires may comprises other semiconductor materials (e.g., silicon carbide).

Turning now to FIG. 1, and block 110 in particular, a mask layer is deposited on a substrate. This is illustrated in FIG. 2C, where a mask layer 240 has been deposited over the semiconductor layer 230 of substrate 200. The mask layer 240 will be patterned for the formation of a wire structure and is ultimately removed, and the mask layer may comprise any suitable material that is amenable to patterning and, further, that can be readily removed (e.g., without removal of the wire structure or removed at a much faster rate than the removal rate of the wire structure). In one embodiment, the mask layer 240 comprises an oxide material (e.g., SiO₂). Any suitable deposition technique may be employed to deposit the mask layer 240, such as physical vapor deposition (PVD), chemical vapor deposition (CVD), etc.

Referring to block 120, the mask layer is patterned for the growth of silicon (or other semiconductor material). This is illustrated in FIGS. 2D through 2F, where a pattern 250 has been formed in the mask layer 240 on substrate 200. A plan view of the substrate and pattern are shown in FIG. 2D, whereas cross-sectional views of the substrate and pattern, as taken along lines I-I and II-II of FIG. 2D, are shown in FIGS. 2E and 2F, respectively. Any suitable photolithography and etching processes may be used to form the pattern 250. In one embodiment, the pattern 250 comprises a first area 251, a second area 252 spaced apart from the first area, and a relatively narrower area 255 extending between the first and second areas 251, 252.

As set forth in block 130, a layer of silicon (or other semiconductor material) is deposited over exposed portions of the substrate within the pattern. This is illustrated in FIGS. 2G through 21, which show a layer of silicon 260 that has been deposited over exposed portions of the silicon layer 230 within pattern 250. In one embodiment, the silicon layer 260 is deposited by selective epitaxial growth of silicon on the underlying silicon layer 230. In a further embodiment, as shown in the figures, overgrowth of the silicon layer 260 is encouraged, such that the silicon layer 260 extends over and onto portions of the mask layer 240 proximate the pattern 250. Such overgrowth leads to the formation of a “mushroom” shaped silicon body within the patterned area of the mask layer 240. The amount of lateral overgrowth over the upper surface of the mask layer 240 is dependent, at least in part, upon the process conditions under which epitaxial silicon growth takes place, as well as the time period over which silicon growth is performed. The silicon body 260 includes a first region 261 formed in the first area 251 of pattern 250, a second region 262 formed in the second area 252 of pattern 250, and a relatively narrower region 265 formed within narrow area 255 of pattern 250 and extending between the first and second regions 261, 262.

At this juncture, it should be noted that the shape of the silicon body (or layer) 260, as well as that of pattern 250, shown in the figures is but one example of a structural shape (and pattern) that may be used to form a wire according to the disclosed embodiments. The actual shape of silicon body 260 (and pattern 250) may be a function of a number of factors, including the growth rate of the semiconductor material (e.g., silicon) from which the wire is to be formed, the amount of overgrowth that is permitted, the oxidation rate of this semiconductor material, the type of device (e.g., a transistor) being formed, as well as others factors.

Referring to block 140 in FIG. 1, the mask layer is then removed. This is illustrated in FIGS. 2J through 2L, where the mask layer 240 has been removed. Any suitable process may be used to remove the mask layer 240, such as a chemical etching process. In one embodiment, where the mask layer 240 comprises SiO₂, the mask material is removed using a solution including hydrofluoric acid (HF). Generally, the process employed to remove the mask layer 240 should remove the mask material without removing the silicon structure 260 and underlying silicon layer 230 of substrate 200 or, alternatively, remove the mask material at a much greater rate than the removal rate of silicon. As shown in FIGS. 2J-2L, after removal of the mask layer 240, the silicon body 260 remains over the silicon layer 230 of substrate 200.

As set forth in block 150, oxidation is then performed to oxidize portions of the silicon (or other semiconductor material). This is illustrated in FIGS. 2M through 20, where portions of the silicon body 260 have been oxidized to form SiO₂. In particular, a portion 281 of the first region 261, a portion 282 of the second region 262, and a portion 285 of the narrow region 265 have been oxidized. Also, the underlying silicon layer 230 has been oxidized (either fully oxidized or, in another embodiment, at least partially oxidized) to form an oxide layer 270. However, as shown in the figures, interior portions of the silicon material remain unoxidized. More specifically, within first region 261 an interior portion 310 remains unoxidized, within second region 262 an interior portion 320 remains unoxidized, and within narrow region 265 an interior portion 350 remains unoxidized. Note also that the unoxidized silicon material 310, 320 within the first and second regions 261, 262 extends down to the insulating layer 220 of substrate 200; however, the unoxidized silicon material 350 embedded within narrow region 265 is separated from the insulating layer 220 by the oxidized portion 285 as well as oxide layer 270.

Any suitable process may be utilized to oxidize the desired portions of the silicon (or other semiconductor) material. In one embodiment, a thermal oxidation process is used to oxidize the silicon. Where thermal oxidation is utilized to form the oxide portions 281, 282, 285 of the silicon body 260, the ratio of the volume of oxide (e.g., SiO₂) to the volume of the silicon regions 261, 262, 265 that is consumed during the oxidation process may be approximately 2 to 1. Also, in one embodiment, the thickness (t) of the oxidized portion 285 surrounding the unoxidized core 350 is approximately one-half the width (w) of the oxidized portion of narrow region 265 that lies between the interior core 350 and the underlying substrate (see FIG. 2N).

Referring to block 160, oxide material is removed. This is illustrated in FIGS. 2P through 2R, where the oxidized portions 281, 282, 285 of the silicon body 260 have been removed. In addition, the oxide layer 270 (e.g., the oxidized silicon layer 230), or at least portions of this layer, has been removed. Any suitable process, such as a chemical etch process, may be employed to remove the oxide. In one embodiment, where the structure 260 is formed from silicon, the oxide may be removed using a solution including HF. Generally, any process that removes the oxide without removing the unoxidized silicon, or that removes the oxide at a much greater rate than the removal rate of silicon, may be used for oxide removal.

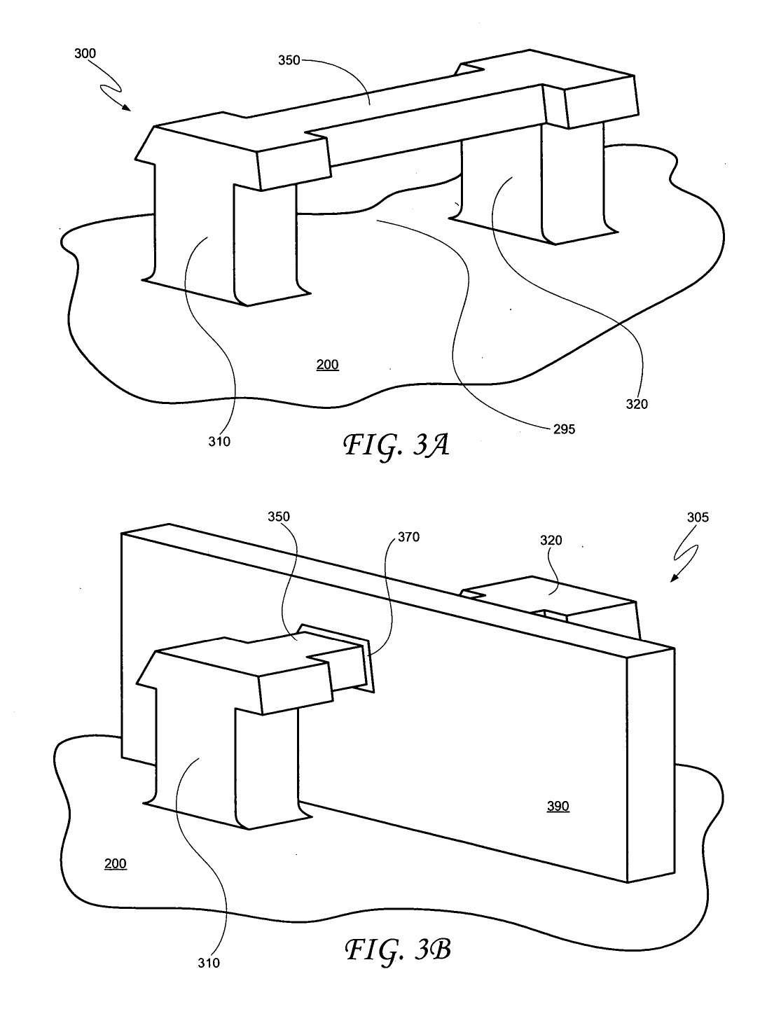

After removal of the oxide, the result is a silicon structure 300 comprising a first anchor 310 that is affixed to substrate 200 (e.g., to insulating layer 220), a second anchor 320 that is affixed to the substrate 200, and a wire 350 that extends between the first and second anchors 310, 320. A perspective view of the silicon structure 300, including the wire 350, is shown in FIG. 3A. Note that the wire 350 is spaced apart from and disposed above the substrate by an undercut region 295 formed by removal of the oxidized portion 285 of narrow region 265. In one embodiment, where the ratio of the thickness (t) of the oxide portion 285 to this oxide layer's width (w) underlying the unoxidized core 350 is at least 2 to 1, separation should occur between the unoxidized core 350 and the underlying substrate when the oxide portion 285 is substantially removed. Note also that the wire 350 is held in place at its ends by the anchoring structures 310, 320, which are affixed to substrate 200, and the wire may be relatively narrower than the anchoring structures. Thus, in one embodiment, what is formed is a free-standing wire extending between opposing anchors which are affixed to the underlying substrate. In one embodiment, this free-standing wire comprises a “nanowire” having a minimum width dimension of approximately 50 nm or less, features sizes which may be beyond the reach of some conventional lithography processes.

The wire structure shown in FIG. 3A may be used to form an electrical device, such as a transistor. Thus, with reference to block 170 in FIG. 1, other structures may be formed to create a transistor or other device. For example, as shown in FIG. 3B, a transistor 305 may be formed by creating a source region in the first anchor 310 and a drain region in the second anchor 320 (e.g., by performing ion implantation, etc.), and electrical connections may be formed with these structures. A gate insulating layer 370 is then formed over and around the wire 350, and a gate electrode 390 is formed over and around the gate insulating layer 370 (and wire 350). The wire 350 provides a channel region between the source and drain regions (anchors 310, 320). In one embodiment, the gate electrode material comprises polysilicon. However, the gate electrode may comprise any other suitable material. For example, in another embodiment, the gate electrode material comprises a metal material (and the gate insulating layer 370 a high-k dielectric material). Note that the gate electrode 390 wraps fully around the wire 350 (and channel region) for optimum gate control of the channel conductance.

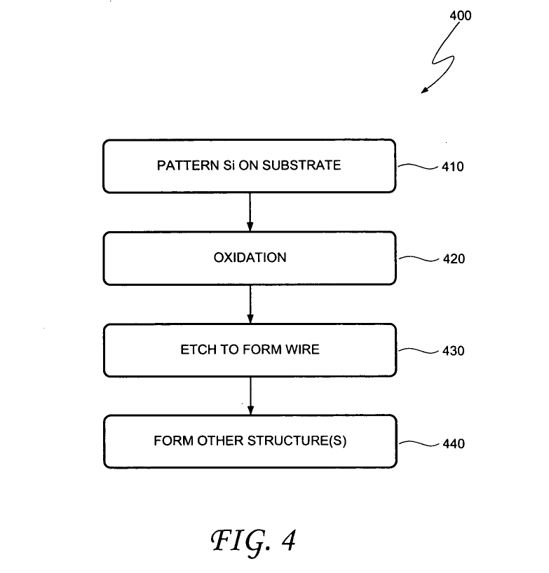

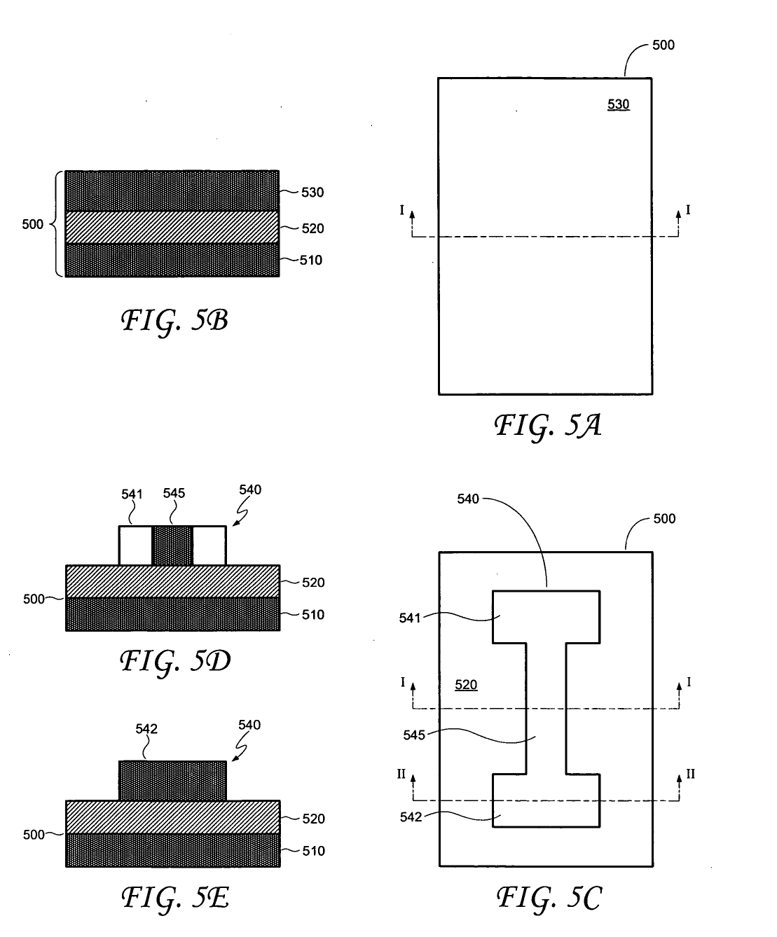

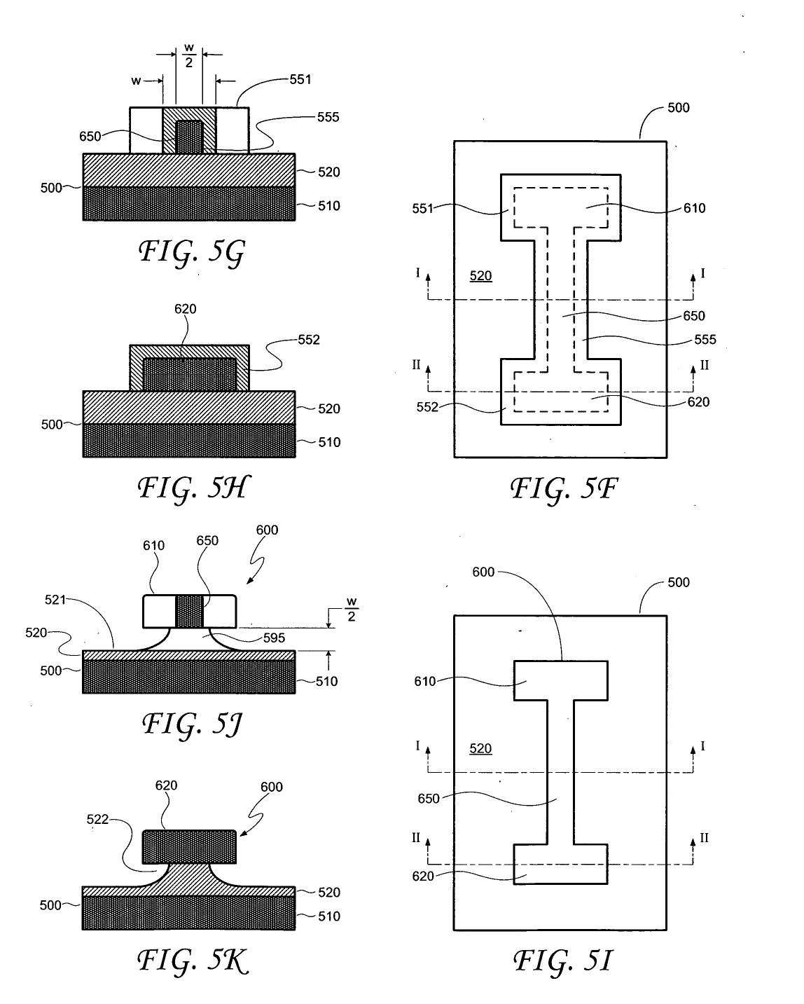

Illustrated in FIG. 4 is another embodiment of a method for forming a wire from silicon or other semiconductor material. The method of FIG. 4 is further illustrated, by way of example, in the schematic diagrams of FIGS. 5A through 5K. Reference should be made to each of FIGS. 5A through 5K, as called out in the text below.

Referring first to FIGS. 5A and 5B, a substrate 500 is shown. A plan view of the substrate is shown in FIG. 5A, and a cross-sectional view of the substrate, as taken along line I-I in FIG. 5A, is shown in FIG. 5B. In one embodiment, the substrate 500 comprises a base layer of a semiconductor material 510, a layer of an insulating material 520 overlying the base layer 510, and a layer of a semiconductor material 530 overlying the insulating layer 520. Substrate 500 may, in one embodiment, comprise a wafer upon which a number of IC devices are to be formed. In one embodiment, the semiconductor layer 530 comprises silicon, and the insulating layer 520 comprises silicon dioxide (SiO₂). In another embodiment, the base layer 510 also comprises silicon. In one embodiment, the substrate 500 comprises a silicon-on-insulator (SOI) wafer. For ease of explanation, in the description set forth below, it is again assumed that the semiconductor layer 530 comprises silicon and, further, that the wire will be formed from silicon. However, it should be understood that the disclosed embodiments are not limited to the use of silicon and, further, that the substrate 500 and disclosed wires may comprises other semiconductor materials (e.g., silicon carbide).

Referring now to FIG. 4, and block 410 in particular, a silicon layer on a substrate is patterned. This is illustrated in FIGS. 5C through 5E, where the silicon layer 510 on substrate 500 has been patterned into a desired shape. A plan view of the substrate and patterned silicon layer are shown in FIG. 5C, whereas cross-sectional views of the substrate and patterned silicon layer, as taken along lines I-I and II-II of FIG. 5C, are shown in FIGS. 5D and 5E, respectively. In one embodiment, as shown in the figures, the silicon layer 530 has been pattered to form a body 540 comprising a first region 541, a second region 542, and a relatively narrower region 545 extending between the first and second regions 541, 542. Any suitable photolithography and etching processes may be utilized to pattern the silicon layer 530.

It should be noted that the shape of the silicon body 540 shown in the figures is but one example of a structural shape that may be used to form a wire according to the disclosed embodiments. The actual shape of silicon body 540 may be a function of a number of factors, such as the oxidation rate of silicon (or other semiconductor material from which the body 540 is formed), the type of device (e.g., a transistor) being formed, as well as others factors.

As set forth in block 420, oxidation is then performed to oxidize portions of the silicon body. This is illustrated in FIGS. 5F through 5H, where portions of the silicon body 540 have been oxidized to form SiO₂. In particular, a portion 551 of the first region 541, a portion 552 of the second region 542, and a portion 555 of the narrow region 545 have been oxidized. However, as shown in the figures, interior portions of the silicon material remain unoxidized. More specifically, within first region 541 an interior portion 610 remains unoxidized, within second region 542 an interior portion 620 remains unoxidized, and within narrow region 545 an interior portion 650 remains unoxidized. Note also that the unoxidized silicon material 610, 620, 650 within the first, second, and third regions 541, 542, 545, respectively, extends down to the insulating layer 520 of substrate 500.

Any suitable process may be utilized to oxidize the desired portions of the silicon (or other semiconductor) material. In one embodiment, a thermal oxidation process is used to oxidize the silicon. Where thermal oxidation is utilized to form the oxide portions 551, 552, 555 of the silicon body 540, the ratio of the volume of oxide (e.g., SiO₂) to the volume of the silicon regions 541, 542, 545 that is consumed during the oxidation process may be approximately 2 to 1. Also, in one embodiment, the width (w/2) of the unoxidized core 650 of narrow region 545 is approximately one-half the width (w) of the narrow region 545 (see FIG. 5G).

Referring to block 430, an etching process is performed to remove the oxide material. This is illustrated in FIGS. 5I through 5K, where the oxidized portions 551, 552, 555 of the silicon structure 540 have been removed. Further, a portion 521 of the insulating layer 520 has been removed. Further, in removing a portion 521 of the insulating layer 520, an undercut etch has been performed in a region 595 underlying the unoxidized narrow silicon region 650 in order to release or separate the silicon core 650 from the substrate 500. Any suitable process, such as a chemical etch process, may be employed to remove the oxide. In one embodiment, where the wire structure is formed from silicon, the oxide material may be removed using a solution including HF. Generally, any process that removes the oxide without removing the unoxidized silicon, or that removes the oxide at a much greater rate than the removal rate of silicon, may be used for oxide removal.

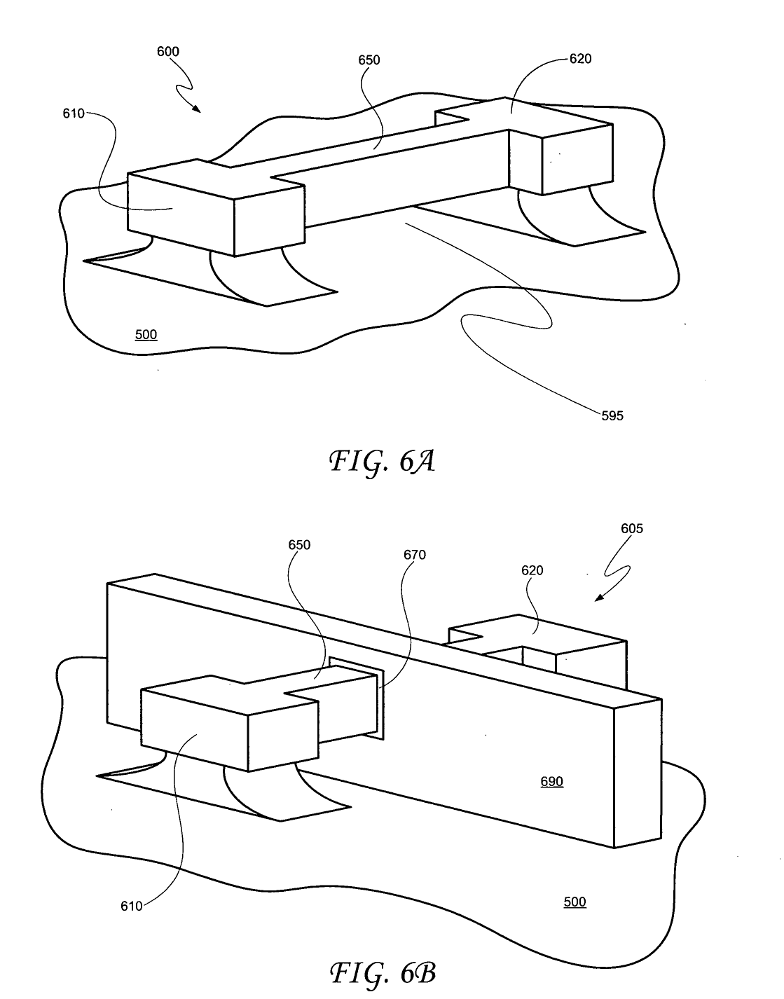

After removal of the oxide, the result is a silicon structure 600 comprising a first anchor 610 that is affixed to substrate 500 (e.g., to the remaining insulating layer 520), a second anchor 620 that is affixed to the substrate 500, and a wire 650 that extends between the first and second anchors 610, 620. A perspective view of the silicon structure 600, including the free-standing wire 650, is shown in FIG. 6A. Note that the wire 650 is spaced apart from and disposed above the substrate by an undercut region 595 formed by removal of the oxidized portion 555 of narrow region 545. In one embodiment, where the ratio of the width (w) of the narrow region 545 to the width (w/2) of the unoxidized core 650 of narrow region 545 to is approximately 2 to 1, separation of the core 650 from the underlying substrate should occur when the oxidized portion 555 of the narrow region 545 is substantially removed (with an approximate thickness w/2 of the insulating layer 520 also being removed). Note also that the wire 650 is held in place at its ends by the anchoring structures 610, 620, which are affixed to substrate 500, and the wire may be relatively narrower than the anchoring structures. Thus, in one embodiment, what is formed is a free-standing wire extending between opposing anchors which are affixed to the underlying substrate. In one embodiment, this free-standing wire comprises a “nanowire” having a minimum width dimension of approximately 50 nm or less, features sizes which may be beyond the reach of some conventional lithography processes.

The wire structure shown in FIG. 6A may be used to form an electrical device, such as a transistor. Thus, with reference to block 440 in FIG. 4, other structures may be formed to create a transistor or other device. For example, as shown in FIG. 6B, a transistor 605 may be formed by creating a source region in the first anchor 610 and a drain region in the second anchor 620 (e.g., by performing ion implantation, etc.), and electrical connections may be formed with these structures. A gate insulating layer 670 is then formed over and around the wire 650, and a gate electrode 690 is formed over and around the gate insulating layer 670 (and wire 650). The wire 650 provides a channel region between the source and drain regions (anchors 610, 620). In one embodiment, the gate electrode material comprises polysilicon; however, it should be understood that the gate electrode may comprise any other suitable conductive material (e.g., a metal material, with the gate insulating layer comprising a high-k dielectric material). Again, the gate electrode 690 wraps fully around the wire 650 (and channel region) for optimum gate control of the channel conductance.

In the embodiments described above (see FIGS. 1 and 4), a semiconductor body may be reduced by thermal oxidation (or other oxidation process) to form a wire. It should be understood, however, that the disclosed embodiments are not limited to use of an oxidation process to perform this reduction. Rather, in other embodiments, alternative ways of performing reduction—such as, for example, etching—may be used in lieu of (or in combination with) oxidation.

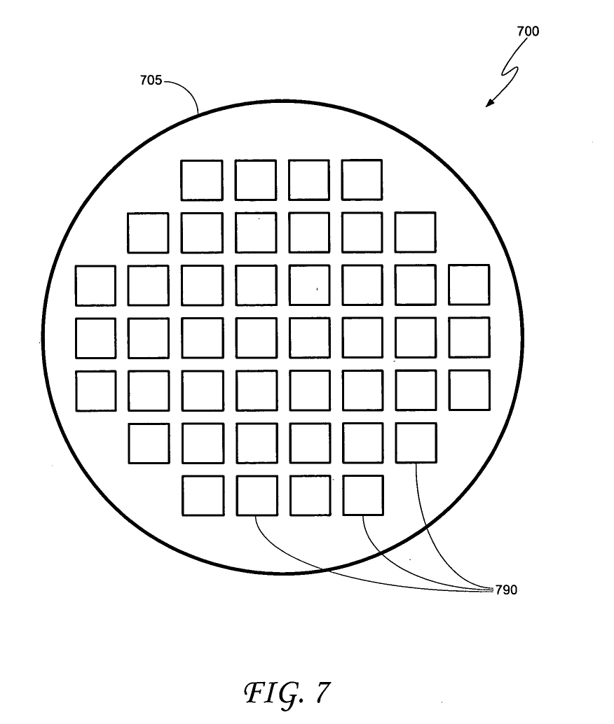

Although a single wire structure 300 is shown in FIGS. 2P-3A and, similarly, a single wire structure 600 is shown in FIGS. 51-6A, it should be understood that, in practice, the disclosed embodiments may be performed at the wafer level and that hundreds of millions of these wire structures (and resulting devices, such as transistors) may be formed on a single wafer. For example, referring to FIG. 7, a plan view of a wafer 700 is shown. The wafer 700 comprises a substrate 705 (e.g., Si, SOI, etc.) upon which integrated circuitry for a number of die 790 has been formed, and wafer 700 is ultimately cut into these separate die 790. Prior to singulation, millions of the disclosed wire structures (and resulting transistors) may be formed on the wafer 700 for each of the die 790.

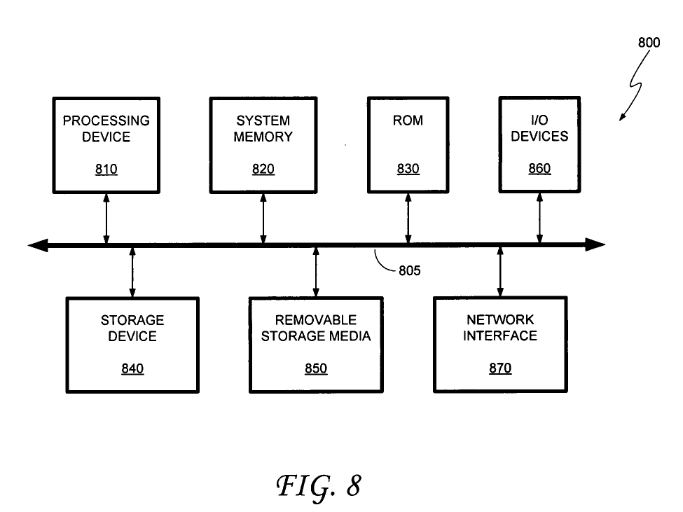

Referring to FIG. 8, illustrated is an embodiment of a computer system 800. Computer system 800 includes a bus 805 to which various components are coupled. Bus 805 is intended to represent a collection of one or more buses—e.g., a system bus, a Peripheral Component Interface (PCI) bus, a Small Computer System Interface (SCSI) bus, etc.—that interconnect the components of system 800. Representation of these buses as a single bus 805 is provided for ease of understanding, and it should be understood that the system 800 is not so limited. Those of ordinary skill in the art will appreciate that the computer system 800 may have any suitable bus architecture and may include any number and combination of buses.

Coupled with bus 805 is a processing device (or devices) 810. The processing device 810 may comprise any suitable processing device or system, including a microprocessor, a network processor, an application specific integrated circuit (ASIC), or a field programmable gate array (FPGA), or similar device. It should be understood that, although FIG. 8 shows a single processing device 810, the computer system 800 may include two or more processing devices.

Computer system 800 also includes system memory 820 coupled with bus 805, the system memory 810 comprising, for example, any suitable type and number of memories, such as static random access memory (SRAM), dynamic random access memory (DRAM), synchronous DRAM (SDRAM), or double data rate DRAM (DDRDRAM). During operation of computer system 800, an operating system and other applications may be resident in the system memory 820.

The computer system 800 may further include a read-only memory (ROM) 830 coupled with the bus 805. During operation, the ROM 830 may store temporary instructions and variables for processing device 810. The system 800 may also include a storage device (or devices) 840 coupled with the bus 805. The storage device 840 comprises any suitable non-volatile memory, such as, for example, a hard disk drive. The operating system and other programs may be stored in the storage device 840. Further, a device 850 for accessing removable storage media (e.g., a floppy disk drive or a CD ROM drive) may be coupled with bus 805.

The computer system 800 may also include one or more I/O (Input/Output) devices 860 coupled with the bus 805. Common input devices include keyboards, pointing devices such as a mouse, as well as other data entry devices, whereas common output devices include video displays, printing devices, and audio output devices. It will be appreciated that these are but a few examples of the types of I/O devices that may be coupled with the computer system 800.

The computer system 800 further comprises a network interface 870 coupled with bus 805. The network interface 870 comprises any suitable hardware, software, or combination of hardware and software that is capable of coupling the system 800 with a network (e.g., a network interface card). The network interface 870 may establish a link with the network (or networks) over any suitable medium—e.g., wireless, copper wire, fiber optic, or a combination thereof—supporting the exchange of information via any suitable protocol—e.g., TCP/IP (Transmission Control Protocol/Internet Protocol), HTTP (Hyper-Text Transmission Protocol), as well as others.

It should be understood that the computer system 800 illustrated in FIG. 8 is intended to represent an exemplary embodiment of such a system and, further, that this system may include many additional components, which have been omitted for clarity and ease of understanding. By way of example, the system 800 may include a DMA (direct memory access) controller, a chip set associated with the processing device 810, additional memory (e.g., a cache memory), as well as additional signal lines and buses. Also, it should be understood that the computer system 800 may not include all of the components shown in FIG. 8.

In one embodiment, a component of computer system 800 includes a wire formed according to the disclosed embodiments. For example, the processing device 810 of system 800 may include one or more transistors (e.g., millions of such devices) having a wire that has been formed according to any of the disclosed embodiments. In one embodiment, the processing device 810 comprises a processor core and/or one or more processing engines, any one of which may include a transistor having a wire formed according to any of the disclosed embodiments. In another embodiment, the processing device comprises a memory (e.g., a SRAM and/or DRAM) having a transistor including a wire formed according to any of the disclosed embodiments. It should be understood, however, that other components of system 800 may include a device formed according to the disclosed embodiments. For example, the system memory 820 may include a memory device (e.g., a DRAM) having a transistor including a wire formed according to any of the disclosed embodiments.

Various embodiments of a method of forming a wire—as well as embodiments of a wire and devices including such a wire—having been described above, the reader will appreciate the advantages of the disclosed embodiments. Dimensions of the wire are controlled by the epitaxial growth rate of silicon (or the growth rate of another semiconductor material) and/or the oxidation rate of silicon (or other semiconductor material). The silicon growth and oxidation processes may be susceptible to a greater degree of control than conventional photolithography processes. For example, the resolution that may be achieved by photolithography may be on the order of 5 nm. In contrast, resolutions on the order of a few to several Angstroms (e.g., 9 Angstroms) may be achieved during the epitaxial silicon growth and oxidation processes. Thus, wires with dimensions and features that may be smaller than that provided by photolithography can be formed. Also, wires can be formed at specific locations on a wafer or other substrate.

The foregoing detailed description and accompanying drawings are only illustrative and not restrictive. They have been provided primarily for a clear and comprehensive understanding of the disclosed embodiments and no unnecessary limitations are to be understood therefrom. Numerous additions, deletions, and modifications to the embodiments described herein, as well as alternative arrangements, may be devised by those skilled in the art without departing from the spirit of the disclosed embodiments and the scope of the appended claims.

1. A method comprising:
forming a body from a semiconductor material on a substrate including a layer of the semiconductor material and an underlying layer of an insulating material, the body including a first region, an opposing second region, and a relatively narrower region extending between the first and second regions;
oxidizing the body to form an oxide, wherein interior portions of the body remain unoxidized; and
removing the oxide, wherein the unoxidized interior portions of the first and second regions form first and second anchors affixed to the substrate and the unoxidized interior portion of the narrower region forms a wire extending between the first and second anchors and spaced apart from the substrate.

2. The method of claim 1, wherein the semiconductor material comprises silicon.

3. The method of claim 2, wherein the substrate comprises a silicon-on-insulator (SOI) wafer, the wafer including a base layer of silicon underlying the insulating layer.

4. The method of claim 1, further comprising:
forming a drain region in the first anchor and a source region in the second anchor;
depositing a layer of a gate insulating material over the wire; and
depositing a gate electrode material over the gate insulating layer.

5. The method of claim 1, wherein the wire has a width dimension of approximately 50 nm or less.

6. A method comprising:
depositing a mask layer on a substrate, the substrate including a first layer of silicon disposed over a layer of an insulating material;
creating a pattern in the mask layer, the pattern having a first area and a second area and a relatively narrower area extending between the first and second areas;
selectively depositing a second layer of silicon over exposed portions of the first silicon layer within the pattern, the second silicon layer extending outward from the pattern and over portions of an upper surface of the mask layer;
removing the mask layer;
oxidizing the first silicon layer to form a first oxide layer overlying the insulating layer and oxidizing the second silicon layer to form a second layer of oxide within the second silicon layer; and
removing at least portions of the first and second oxide layers, wherein silicon remaining in the first and second areas of the pattern form first and second anchors affixed to the substrate and silicon remaining in the narrower area forms a wire extending between the first and second anchors and spaced apart from the substrate.

7. The method of claim 6, wherein the substrate comprises a silicon-on-insulator (SOI) substrate, the substrate further including a silicon base underlying the insulating layer.

8. The method of claim 6, further comprising:
forming a drain region in the first anchor and a source region in the second anchor;
depositing a layer of a gate insulating material around the wire; and
depositing a gate electrode material over the gate insulating layer.

9. The method of claim 6, wherein the wire has a width dimension of approximately 50 nm or less.

10. A method comprising:
patterning a semiconductor layer of a substrate to form a body, the substrate including a layer of an insulating material underlying the semiconductor layer, the body including a first region, a second region, and a relatively narrower region extending between the first and second regions;
oxidizing the semiconductor body to form an oxide, wherein interior portions of the body remain unoxidized; and
etching the oxide, wherein the unoxidized interior portions of the first and second regions form first and second anchors affixed to the substrate and the unoxidized interior portion of the narrower body is undercut etched to form a wire spaced apart from the substrate and extending between the first and second anchors.

11. The method of claim 10, wherein the semiconductor layer comprises silicon.

12. The method of claim 11, wherein the substrate comprises a silicon-on-insulator (SOI) wafer, the wafer including a base layer of silicon underlying the insulating layer.

13. The method of claim 10, further comprising:
forming a drain region in the first anchor and a source region in the second anchor;
depositing a layer of a gate insulating material over the wire; and
depositing a gate electrode material over the gate insulating layer.

14. The method of claim 10, wherein the wire has a width dimension of approximately 50 nm or less.

15. A semiconductor structure comprising:
a first anchor affixed to a substrate;
a second anchor affixed to the substrate; and
a relatively narrower wire extending between the first and second anchors and spaced apart from the substrate.

16. The apparatus of claim 15, further comprising:
a layer of an insulating material disposed over the wire; and
a layer of a conductive material disposed over the insulating layer.

17. The apparatus of claim 15, wherein the substrate comprises a wafer including the semiconductor material.

18. The apparatus of claim 15, wherein the semiconductor material comprises silicon.

19. The apparatus of claim 15, wherein the wire has a width dimension of approximately 50 nm or less.

20. A device comprising:
a substrate; and
a transistor disposed on the die, the transistor including
a first anchor affixed to the substrate, the first anchor providing a source region,
a second anchor affixed to the substrate, the second anchor providing a drain region,
a relatively narrower wire extending between the first and second anchors and spaced apart from the substrate, the wire providing a channel region between the source and drain regions,
a layer of a gate insulating material disposed over the wire, and
a layer of a gate electrode material disposed over the gate insulating layer.

21. The device of claim 20, wherein the first anchor, the second anchor, and the wire comprise silicon.

22. The device of claim 20, wherein the wire has a width dimension of approximately 50 nm or less.

23. A system comprising:
a memory device; and
a processing device coupled with the memory device, the processing device having a transistor, the transistor including
a first anchor affixed to a substrate of the processing device, the first anchor providing a source region,
a second anchor affixed to the substrate, the second anchor providing a drain region,
a relatively narrower wire extending between the first and second anchors and spaced apart from the substrate, the wire providing a channel region between the source and drain regions,
a layer of a gate insulating material disposed over the wire, and
a layer of a gate electrode material disposed over the gate insulating layer.

24. The system of claim 23, wherein the first anchor, the second anchor, and the wire comprise silicon.

25. The system of claim 23, wherein the wire has a width dimension of approximately 50 nm or less.

26. The system of claim 23, wherein the transistor comprises part of a memory formed on the substrate.

27. The system of claim 26, wherein the memory comprises a static random access memory (SRAM) or a dynamic random access memory (DRAM).

28. The system of claim 23, wherein the transistor comprises part of a logic circuit.
